(19) United States
(12) Patent Application Publication
(10) Pub. No.: US 2013/0265073 A1
(43) Pub. Date: Oct. 10, 2013

(54) Probe Card And Manufacturing Method Therefor

(71) Applicants: Hirofumi Nakano, Amagasaki-shi (JP); Taishi Uemura, Amagasaki-shi (JP); Kazuhiro Matsuda, Amagasaki-shi (JP)

(72) Inventors: Hirofumi Nakano, Amagasaki-shi (JP); Taishi Uemura, Amagasaki-shi (JP); Kazuhiro Matsuda, Amagasaki-shi (JP)

(73) Assignee: Japan Electronic Materials Corporation, Hyogo (JP)

(21) Appl. No.: 13/993,690

(22) PCT Filed: Jan. 16, 2011
(86) PCT No.: PCT/JP2011/050585

§ 371 Date: Jun. 13, 2013

(51) Int. Cl. G01R 3/00; G01R 1/073

(52) U.S. Cl. CPC G01R 3/00; G01R 1/07342
USPC 324/754.07; 29/831

(57) ABSTRACT

The present invention provides a ST board 2 that is formed with an lower surface electrode 22; a unit attachment plate 3 that is fastened on the ST board 2 and formed with an opening part 31 exposing the lower surface electrode 22; a probe unit 5 that includes a probe substrate 50 formed with a contact probe 51 and a probe electrode 52 and is fastened on the unit attachment plate 3; and an electrically conductive wire 54 that connects the lower surface electrode 22 and the probe electrode 52 to each other through the opening part 31. The probe unit 5 can be fastened on the ST board 2 with the unit attachment plate 3 intervening, and through the opening part 31 of the unit attachment plate 3, the probe electrode 51 and the lower surface electrode 22 can be electrically connected to each other.

### FIELD OF THE INVENTION

The present invention relates to a probe card, and more particularly, to improvement of a probe card in which a probe substrate formed with contact probes is fastened on a wiring substrate.

### BACKGROUND ART

A manufacturing process of a semiconductor device includes an inspection step of inspecting electrical characteristics of an electronic circuit formed on an inspection object such as a semiconductor wafer, and to inspect the electrical characteristics, a tester and a probe card are used. The tester is a signal input/output unit that supplies a test signal to the inspection object and detects a response signal from the inspection object. On the other hand, the probe card is a device that electrically connects inspection terminals of the tester to minute terminal electrodes on the inspection object.

In a well-known probe card, a number of external terminals for connecting the tester are arranged near an outer circumference of a wiring substrate at wide pitches; a number of contact probes that are brought into contact with the terminal electrodes of the inspection object are arranged near the center of the wiring substrate at narrow pitches; and the contact probes and corresponding external terminals are electrically connected to each other. By using such a probe card, the inspection terminals of the tester can be connected to the minute electrodes on the inspection object.

FIG. 23 is a diagram illustrating a situation at the time of repairing a conventional probe card, in which (a) and (b) illustrate situations before and after removal of one of probe units 5, respectively. The probe card is configured to include: the probe units 5 each in which on a probe substrate 50, contact probes 51 are arranged; a main board 1 formed with external terminals 11; and an ST (Space Transformer) board 2 and a guide plate 13 that are arranged between the probe units 5 and the main board 1.

The main board 1 and the ST board 2 are respectively wiring substrates on which wiring lines for increasing electrode pitches are formed. The guide plate 13 is a structure that retains the ST board 2, and electrodes on the main board 1 and ST board 2 are electrically connected to each other through an interposer incorporated in the guide plate 13. For this reason, the contact probes 51 are electrically connected to corresponding external terminals 11 through respective wiring lines on the probe substrates 50, ST board 2, and main board 1, and the interposer in the guide plate 13. By employing such a configuration, the contact probes 51 can be arranged at narrower pitches, and also at the time of breakage of a contact probe 51, by replacing a corresponding one of the probe units 5, the probe card can be repaired.

The probe card is repaired by using a shear tool 6 provided with a wedge-shaped protrusion 61. Each of the probe substrates 50 is fastened on the ST board 2 through a bonding layer 5B. By pressing the wedge-shaped protrusion 61 of the shear tool 6 into the bonding layer 5B, the probe unit 5 is torn off from the ST board 2. That is, by using the shear tool 6 to spread out a distance between a corresponding probe substrate 50 and the ST board 2, the bonding layer 5B is sheared off to remove the probe substrate 50 from the ST board 2. After that, by attaching a new probe unit 5, the probe card can be repaired.

### DISCLOSURE OF THE INVENTION

### Problems to be Solved by the Invention

In the conventional probe card, at the time of replacing the probe unit 5, the shear tool 6 is used to tear off the probe substrate 50 from the ST board 2. Due to this, there is a problem that at the time of removing the probe unit 5, the ST board 2 may be damaged. For example, a wiring pattern formed on the ST board 2 may be peeled off together with the probe unit 5.

Also, regarding the ST board 2 formed with the wiring pattern and an insulating layer, a surface thereof is not flat, and therefore there is a problem that at the time of fastening the probe unit 5 on the ST board 2, it is not easy to improve positioning accuracy of the probe unit 5. Further, there is a problem that it is not easy to surely fix the probe unit 5 on the ST board 2.

The present invention is made in consideration of the above circumstances, and intended to facilitate repair of a probe card. In particular, the present invention is intended to provide a probe card that suppresses damage to a wiring substrate at the time of removing a probe unit. Also, the present invention is intended to provide a probe card that improves positioning accuracy of a probe unit with respect to a wiring substrate. Further, the present invention is intended to provide a probe card that can be easily attached with a probe unit.

### Means Adapted to Solve the Problems

A probe card according to a first aspect of the present invention is provided with: a wiring substrate that is formed with an electrode terminal; a unit attachment plate that is fastened on the wiring substrate and formed with an opening part exposing the electrode terminal; a probe unit that includes a probe substrate formed with a contact probe and a probe electrode and is fastened on the unit attachment plate; and an electrically conductive wire that connects the electrode terminal and the probe electrode to each other through the opening part.

According to such a configuration, the probe unit can be fastened on the wiring substrate with the unit attachment plate intervening, and also through the opening part of the unit attachment plate, the probe electrode of the probe unit and the electrode terminal of the wiring substrate can be electrically connected to each other. For this reason, damage to the wiring substrate at the time of replacing the probe unit can be suppressed to facilitate repair of the probe card. Also, by fastening the probe unit on the unit attachment plate, as compared with the case of fastening on the wiring substrate, positioning accuracy of the probe unit can be improved. Further, by fastening on the unit attachment plate that is flatter than the wiring substrate, the probe unit can be surely fastened.

A probe card according to a second aspect of the present invention is, in addition to the above configuration, configured such that two or more said electrode terminals are exposed from the opening part in common, and two or more said probe electrodes of the probe unit are respectively connected to corresponding ones of the electrode terminals through two or more electrically conductive wires passing through the opening part in common.

According to such a configuration, the two or more electrically conductive wires passing through the common opening part can electrically connect the two or more probe electrodes and the two or more electrode terminals to each other. For this reason, it is not necessary to form the opening part with relating the opening part to the electrically conductive wire one-on-one, and therefore even in the case where a pitch between the electrode terminals is narrow, the opening part can be easily formed.

A probe card according to a third aspect of the present invention is, in addition to the above configuration, configured such that two or more probe units are arranged on the unit attachment plate in common, and the opening part has a long narrow shape that extends along outer edge parts of the probe units.

According to such a configuration, the two or more probe units can be arranged on the wiring substrate at narrow pitches.

A probe card manufacturing method according to a fourth aspect of the present invention is provided with: a step of fastening a probe substrate formed with a contact probe and a probe electrode on a unit attachment plate; a step of fastening the unit attachment plate on a wiring substrate with relating an opening part of the unit attachment plate to an electrode terminal of the wiring substrate; and a step of performing wire bonding between the probe electrode and the electrode terminal exposed through the opening part.

According to such a configuration, the probe unit can be fastened on the wiring substrate with the unit attachment plate intervening, and also, through the opening part of the unit attachment plate, the probe electrode of the probe unit and the electrode terminal of the wiring substrate can be electrically connected to each other. For this reason, damage to the wiring substrate at the time of replacing the probe unit can be suppressed to facilitate repair of the probe card. Also, by fastening the probe unit on the unit attachment plate, as compared with the case of fastening on the wiring substrate, positioning accuracy of the probe unit can be improved. Further, by fastening on the unit attachment plate that is flatter than the wiring substrate, the probe unit can be surely fastened.

A probe card manufacturing method according to a fifth aspect of the present invention is, in addition to the above configuration, provided with a step of, after the fastening on the unit attachment plate, removing a part of the probe substrate to expose the opening part covered by the probe substrate.

According to such a configuration, on the unit attachment plate, the probe substrate having an arbitrary shape can be attached. Accordingly, positioning accuracy of the probe substrate with respect to the unit attachment plate can be improved. Also, in the case of removing the part of the probe substrate to thereby split the probe substrate into two or more probe substrates, the two or more probe substrates can be simultaneously fastened on the unit attachment plate to facilitate work of attaching the probe substrates.

A probe card manufacturing method according to a sixth aspect of the present invention is, in addition to the above configuration, provided with a step of forming a split groove on the probe substrate, and configured to, in the step of removing the part of the probe substrate, apply impact to the probe substrate to split the probe substrate along the split groove.

According to such a configuration, by applying the impact after the fastening on the wiring substrate, the part of the probe substrate can be removed to expose the opening part covered by the probe substrate. For this reason, in the case of removing the part of the probe substrate by cutting work, damage to the contact probe can be suppressed.

A probe card manufacturing method according to a seventh aspect of the present invention is, in addition to the above configuration, configured to, in the step of removing the part of the probe substrate, use a dicing machine to cut the probe substrate.

A probe card manufacturing method according to an eighth aspect of the present invention is, in addition to the above configuration, provided with a step of forming a bonding layer on the wiring substrate with relating the bonding layer to a formation area for the contact probe and the probe electrode, and configured to, in the step of fastening the probe substrate on the wiring substrate, through the bonding layer, fasten the probe substrate on the wiring substrate.

### Effects of the Invention

In the probe card according to the present invention, the probe unit is fastened on the unit attachment plate; the unit attachment plate is fastened on the wiring substrate; and through the opening part of the unit attachment plate, the probe electrode on the probe unit and the electrode terminal on the wiring substrate are electrically connected to each other. For this reason, damage to the wiring substrate at the time of replacing the probe unit can be suppressed to facilitate repair of the probe card. Also, by fastening the probe unit on the unit attachment plate, as compared with the case of fastening on the wiring substrate, positioning accuracy of the probe unit can be improved. Further, the probe unit can be easily fastened on the probe card.

Also, in the probe card manufacturing method according to the present invention, after the fastening on the unit attachment plate, the part of the probe substrate is removed to expose the opening part of the unit attachment plate, which is covered by the probe substrate. According to such a manufacturing method, the probe substrate having an arbitrary shape can be attached on the unit attachment plate, and positioning accuracy of the probe substrate with respect to the unit attachment plate can be improved. Also, work of attaching the probe substrate can be facilitated.

### BRIEF DESCRIPTION OF THE DRAWINGS

FIG. 1 is the plain diagram illustrating an example of a schematic configuration of a probe card 100 according to a first embodiment of the present invention.

FIG. 2 is a lateral side view of the probe card 100 in FIG. 1.

FIG. 3 is an enlarged view illustrating the lower surface of the probe card 100 in FIG. 1.

FIG. 4 is an enlarged cross-sectional view in case of cutting the probe card 100 in FIG. 1 along an A-A section line.

FIG. 5 is a diagram illustrating an example of a detailed configuration of the unit attachment plate 3 in FIG. 1.

FIG. 6 is an appearance diagram illustrating an example of a detailed configuration of the ST board 2 in FIG. 1.

FIG. 7 is a schematic diagram illustrating an example of a method for forming electrically conductive wires 54.

FIG. 8 is an explanatory diagram schematically illustrating an example of a method for manufacturing the probe card 100 in FIG. 1.

FIG. 9 is a diagram illustrating a situation at the time of repairing the probe card 100 in FIG. 1.

FIG. 10 is the plain diagram illustrating an example of a schematic configuration of the probe card 101 according to the second embodiment of the present invention.

FIG. 11 illustrates a lateral side of the probe card 101 in FIG. 10.

FIG. 12 is an enlarged view enlarging the lower surface of the probe card 101 in FIG. 10.

FIG. 13 is the explanatory diagram schematically illustrating an example of a method for manufacturing the probe card 101 in FIG. 10.

FIG. 14 is the explanatory diagram schematically illustrating an example of a method for manufacturing the probe card 101 in FIG. 10.

FIG. 15 is the explanatory diagram schematically illustrating an example of a method for manufacturing the probe card 101 in FIG. 10.

FIG. 16 is an explanatory diagram schematically illustrating an example of the method for manufacturing the probe card 101 according to the third embodiment of the present invention.

FIG. 17 illustrates a cross-sectional view in the case of cutting along a D-D section line in (b) of FIG. 16.

FIG. 18 is the lateral side view illustrating an example of a schematic configuration of the probe card 102 according to the fourth embodiment of the present invention.

FIG. 19 is the explanatory diagram schematically illustrating the method for manufacturing the probe card 101 in FIG. 18.

FIG. 20 is the explanatory diagram schematically illustrating the method for manufacturing the probe card 101 in FIG. 18.

FIG. 21 is an explanatory diagram schematically illustrating the example of the method for manufacturing the probe card 102 according to the fifth embodiment of the present invention.

FIG. 22 illustrates a cross-sectional view in the case of cutting along an E-E section line in (b) of FIG. 21.

FIG. 23 is a diagram illustrating a situation at the time of repairing a conventional probe card.

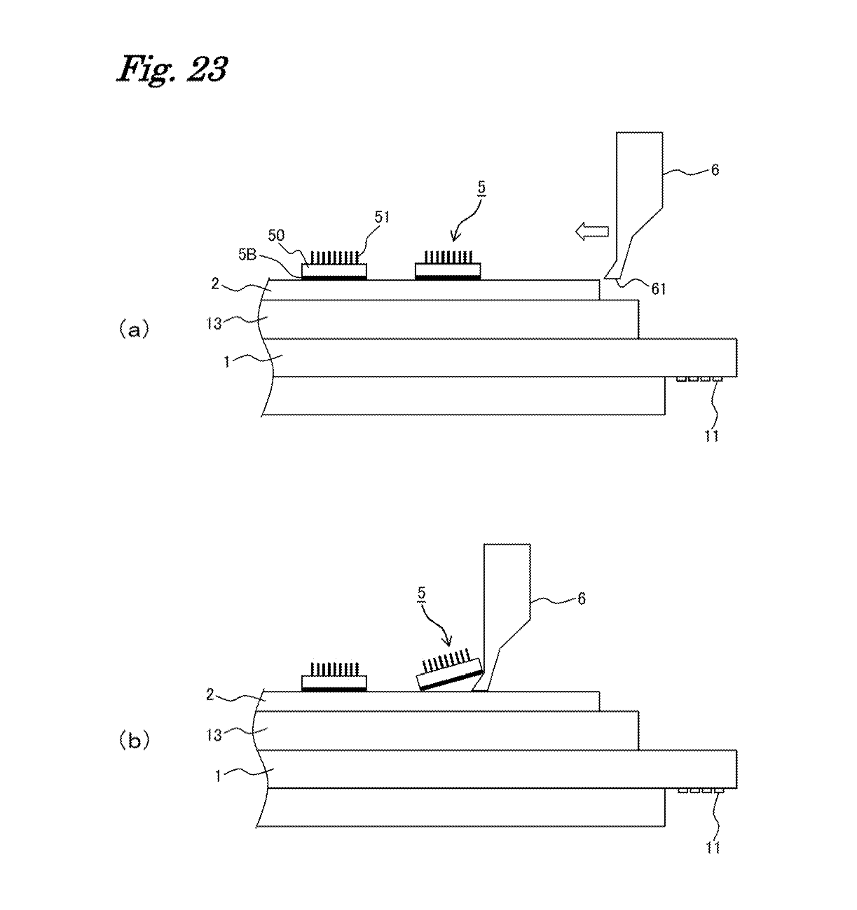

### DESCRIPTION OF EMBODIMENTS

### First Embodiment

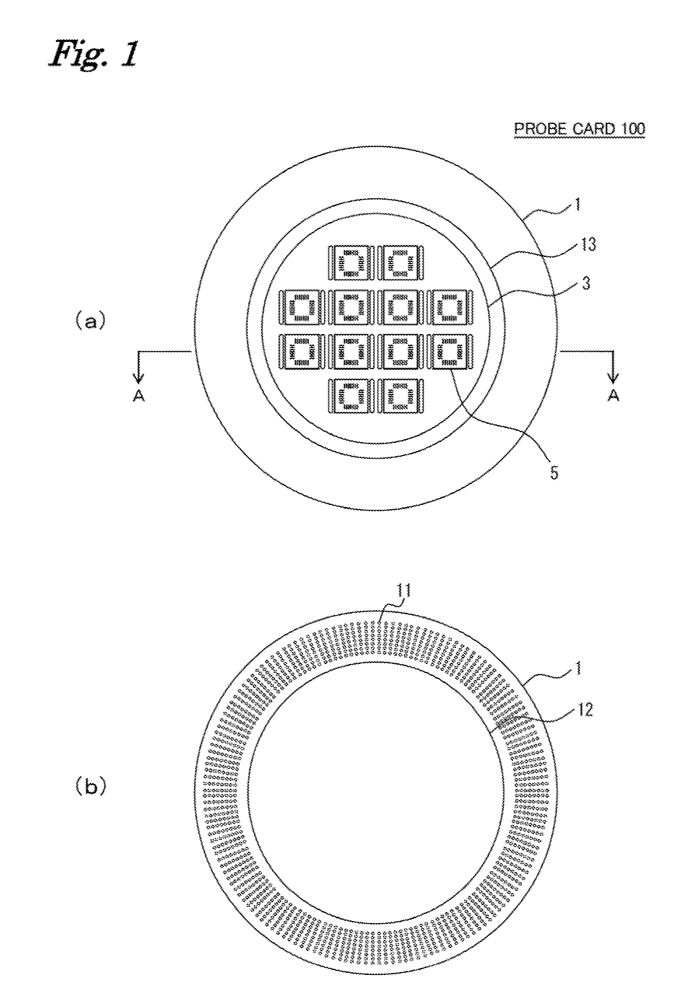

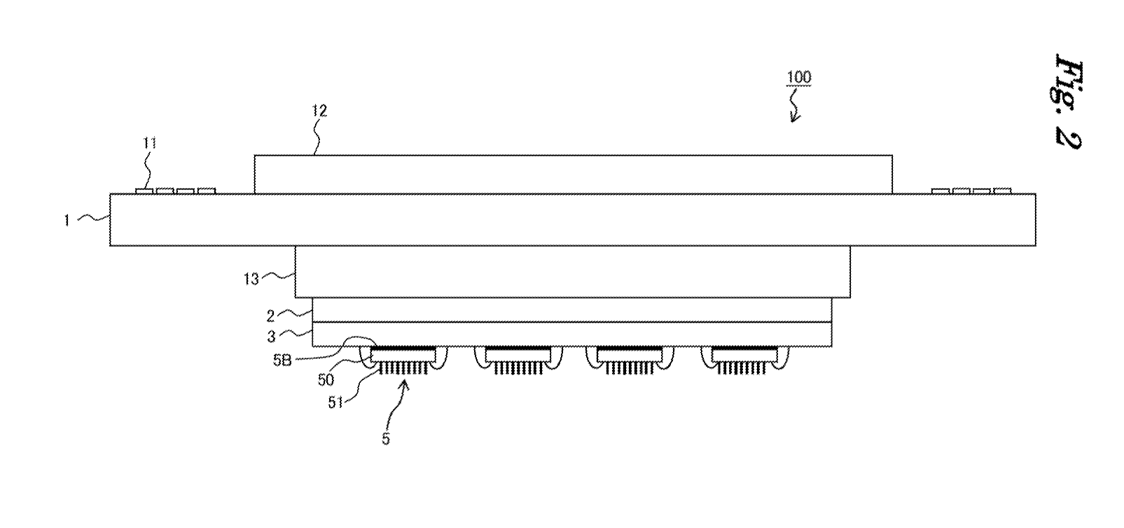

FIGS. 1 and 2 are appearance diagrams illustrating an example of a schematic configuration of a probe card 100 according to a first embodiment of the present invention. (a) in FIG. 1 illustrates a lower surface of the probe card 100, and (b) in the same diagram illustrate an upper surface of the probe card 100. Also, FIG. 2 illustrates a lateral side of the probe card 100.

The probe card 100 is an inspection device for inspecting electrical characteristics of an electronic circuit formed on an inspection object such as a semiconductor wafer, and configured to include a main board 1, an ST board 2, a unit attachment plate 3, and probe units 5. In general, at the time of inspection, the contact probe 100 is horizontally retained with an arrangement surface for contact probes 51 facing downward; however, at the time of manufacturing or repair, the probe card 100 is retained with the arrangement surface for the contact probes 51 facing upward. In the present description, for convenience, the arrangement surface for the contact probes 51 is referred to as the lower surface of the probe card 100.

The main board 1 is a wiring substrate detachably attached to a prober (not illustrated), for example, a disk-shaped printed circuit board (PCB), and configured to include external terminals 11, a reinforcing plate 12, and a guide plate 13. The external terminals 11 are electrode terminals for making connections to a tester (not illustrated), and formed around an outer edge part of an upper surface of the main board 1. The reinforcing plate 12 is a metal block for preventing the main board 1 from being thermally deformed, and fastened near the central part of the upper surface of the main board 1. The guide plate 13 is a supporting member that supports the ST board 2, and fastened to the central part of a lower surface of the main board 1 to support the ST board 2 so as to keep a predetermined height from the main board 1.

The ST board 2 is a wiring substrate that increases an electrode pitch, for example, a disk-shaped printed circuit board (PCB). That is, the ST board 2 makes electrical connections between probe electrodes 52 on the probe units 5 and electrodes on the main board 1, which are formed at wider pitches than a pitch between the probe electrodes 52.

The unit attachment plate 3 is a plate-like supporting member that supports the probe units 5, for example, a metal plate, and through a bonding layer 5B fastened with the probe units 5. The unit attachment plate 3 is attached on the ST board 2 with an upper surface thereof facing to a lower surface of the ST board 2. On a lower surface of the unit attachment plate 3, the one or more probe units 5 are bonded with being mutually separated.

Each of the probe units 5 includes a probe substrate 50 formed with the contact probes 51. The probe substrate 50 is a substrate made of an electrically non-conductive material fastened on the unit attachment plate 3 through the bonding layer 5B, for example, a rectangular-shaped flat plate made of silicon single crystal. The contact probes 51 are probes that are brought into abutting contact with minute electrode pads formed on the inspection object, and arranged on a lower surface of the probe substrate 50, i.e., arranged on a principal surface on a side opposite to the unit attachment plate 3.

The probe units 5 are related to one or more electronic circuits to be inspected, and the contact probes 51 are related to electrode pads of the electronic circuits. For this reason, on each of the probe substrates 50, the multiple contact probes 51 are formed by micromachining leading to MEMS (Micro Electro Mechanical Systems). The contact probes 51 are electrically connected to the external terminals 11 through respective wiring lines on the probe substrates 50, ST board 2, and main board 1, and by bringing the contact probes 51 into abutting contact with the inspection object, the electronic circuits to be inspected and the tester can be electrically connected to each other.

In the probe card 100, the probe units 5 are bonded not to the ST board 2 but to the unit attachment board 3. For this reason, at the time of replacing any of the probe units 5 to repair the probe card 100, the old probe unit 5 is torn off from the unit attachment plate 3, and a new probe unit 5 is attached on the unit attachment plate 3. Accordingly, at the time of repair, the ST board 2 can be suppressed from being damaged.

In addition, the lower surface of the unit attachment plate 3 can be easily flattened as compared with the ST board 2 formed with a wiring pattern and an insulating protective film, and therefore the attachment of the probe unit 5 can be facilitated. For example, positioning of the probe unit 5 can be facilitated, or fixation of the probe unit 5 can be facilitated.

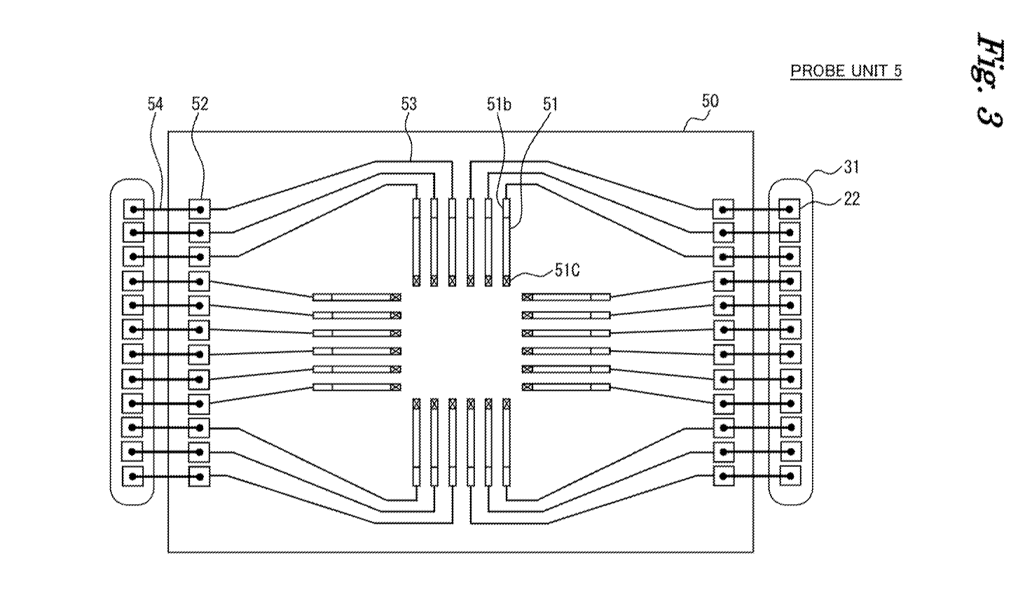

FIG. 3 is an enlarged view illustrating the part of the lower surface of the probe card 100 in FIG. 1 with enlarging the part, in which one of the probe units 5 and its periphery are illustrated. In the probe unit 5, on the rectangular-shaped probe substrate 50, the contact probes 51, probe electrodes 52, and wiring pattern 53 are arranged.

Each of the contact probes 51 is provided with: a contact part 51c that is brought into abutting contact with the inspection object; and a base part 51b that is supported by the probe substrate 50, and has cantilever structure that elastically brings the contact part 51c into abutting contact with the inspection object. Also, the contact probes 51 are orderly arranged such that the contact parts 51c are positioned on a central side of the probe substrate 50 and the base parts 51b are positioned on outer edge sides of probe substrate 50. Also, the electronic circuits to be inspected are typically formed in a rectangular area on a semiconductor wafer, and along an outer edge part of the rectangular area, a number of electrode pads are formed. For this reason, the multiple contact probes 51 constituting the probe unit 5 are orderly arranged such that the contact parts 51c form a rectangular shape.

The probe electrodes 52 are electrode terminals respectively related to the contact probes 51; arranged near an outer edge part of the probe substrate 50; and through the wiring pattern 53, electrically connected to the base parts 51b of the corresponding contact probes 51. Here, along a pair of opposite sides of the probe substrate 50, the multiple probe electrodes 52 are orderly arranged. Also, the probe electrodes 52 are, through electrically conductive wires 54, connected to lower surface electrodes 22 of the ST board 2, which are exposed through opening parts 31 of the unit attachment plate 3.

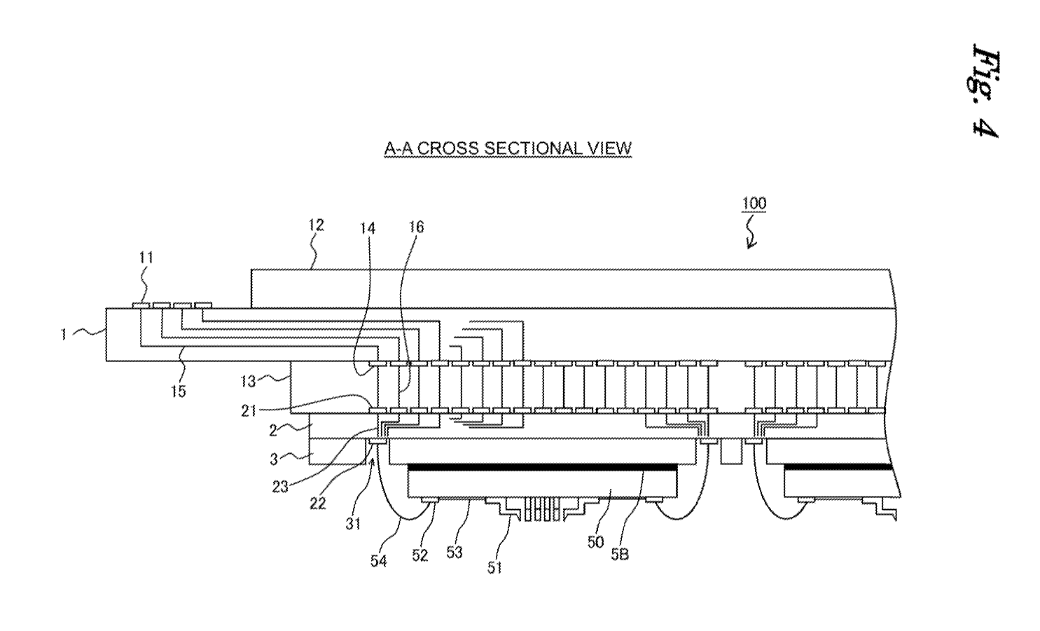

FIG. 4 is an enlarged cross-sectional view illustrating a cross section of the probe card 100 in FIG. 1 with enlarging the cross section, in which part of the cross section cut along an A-A section line is schematically illustrated.

The main board 1 is provided with: the internal electrodes 14 that are formed near the central part of the lower surface; the external terminals 11 that are formed near the outer edge part of the upper surface; and a wiring pattern 15 that electrically connects the internal electrodes 14 and the external electrodes 11 to each other. The wiring pattern 15 extends from the central part to the outer edge part of the main board 1, and a wiring pitch thereof increases towards the outer edge part. For this reason, an electrode pitch between the external terminals 11 is large as compared with an electrode pitch between the internal electrodes 14. Also, the guide plate 13 incorporates connecting pins 16 referred to as an interposer to electrically connect the internal electrodes 14 of the main board 1 and upper surface electrodes 21 of the ST board to each other, which respectively face each other.

The ST board 2 is provided with the upper surface electrodes 21, lower surface electrodes 22, and a wiring pattern 23. The upper surface electrodes 21 are electrode terminals formed on an upper surface of the ST board, and through the connecting pins 16, connected to the internal electrodes 14 of the main board 1. The lower surface electrodes 22 are electrode terminals formed on the lower surface of the ST board, and through the electrically conductive wires 54 passing through the opening parts 31 of the unit attachment plate 3, connected to the corresponding probe electrodes 52. For this reason, a pitch between the upper surface electrodes 21 is larger than that between the lower surface electrodes 22, and by increasing a wiring pitch in the ST board 2, the main board 1 and the probe units 5 are electrically connected to each other. The wiring pattern 23 includes wiring lines that electrically connect the upper surface electrodes 21 and the lower surface electrodes 22 to each other.

The unit attachment plate 3 is a metal plate for supporting the probe units 5 and protecting the ST board 2 from stress at the time of repair. The unit attachment plate 3 is formed with the opening parts 31 that penetrate therethrough in a plate thickness direction and expose the lower surface electrodes 22 of the ST board 2. By performing wire bonding through the opening parts 31, the probe electrodes 52 of the probe units 5 can be electrically connected to the lower surface electrodes 22. The electrically conductive wires 54 are bonding wires formed by using a bonding machine, and arranged in the air except for both ends respectively fastened to the probe electrodes 52 and the lower surface electrodes 22.

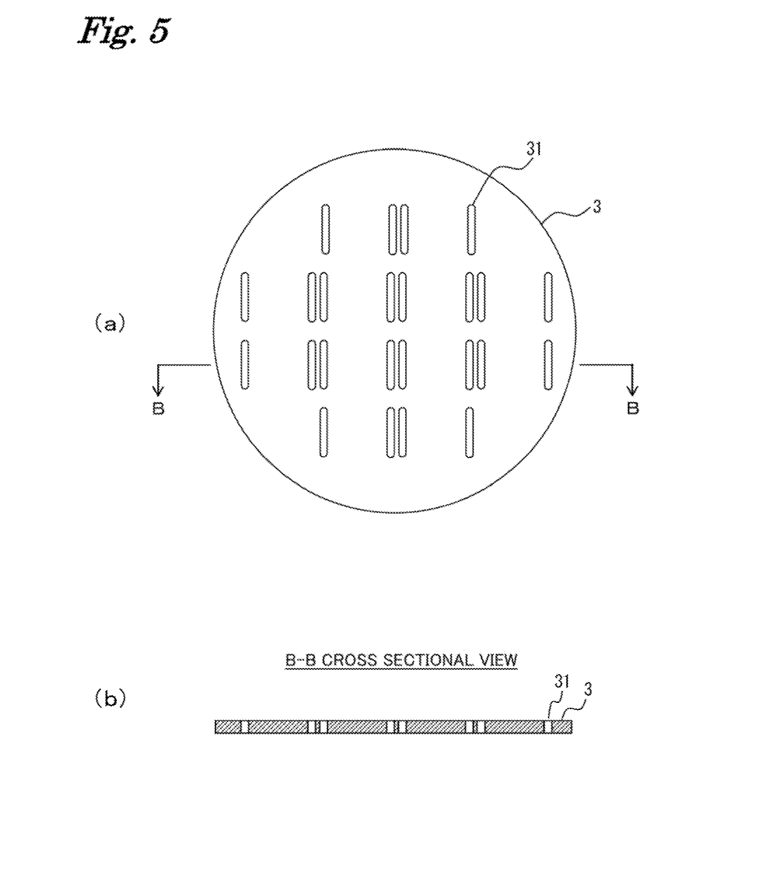

FIG. 5 is a diagram illustrating an example of a detailed configuration of the unit attachment plate 3 in FIG. 1. (a) in the diagram is a plan view illustrating an appearance of the unit attachment plate 3, and (b) in the diagram is a cross-sectional view illustrating a cross section along a B-B section line.

The unit attachment plate 3 is formed with the opening parts 31 corresponding to the lower surface electrodes 22. The opening parts 31 are, without overlapping with arrangement areas for the probe units 5, formed around the probe units 5. Here, for each of the probe units 5, two opening parts 31 that respectively have long narrow shapes extending along the pair of opposite sides of the probe substrate 50 are formed, and from one of the opening parts 31, two or more lower surface electrodes 22 are exposed. That is, the slit-like opening part 31 is formed in the unit attachment plate 3 with being related to a corresponding one of lines of the probe electrodes 52, and through the opening part 31, two or more lower surface electrodes 22 corresponding to the respective probe electrodes 52 forming the one line are exposed.

In addition, as the unit attachment plate 3, a plate-like body made of a material other than metal, for example, a ceramic board can also be employed; however, a metal plate can be accurately and easily perforated by punching, and therefore it is desirable to use a metal plate. Also, in consideration of workability of the wire bonding, it is desirable to form the opening parts 31 each of which an inner surface penetrating through the unit attachment plate 3 has a taper shape, and a size on the probe unit 5 side is larger than that on the ST board 2 side. Also, by exposing two or more lower surface electrodes 22 through one and the same opening part 31, the opening parts 31 can be easily formed as compared with the case of forming an opening part 31 for each of the probe electrodes 52. Further, by forming a cross section of each of the opening parts 31 in the long narrow shape, the two or more probe units 5 can be arranged at narrow pitches.

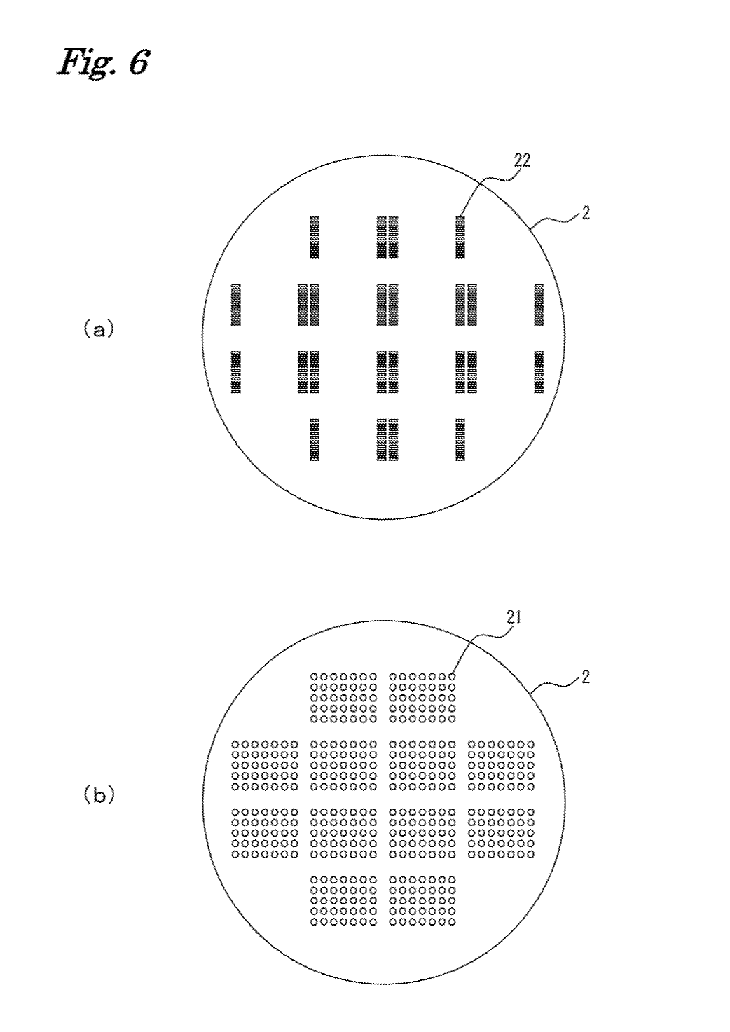

FIG. 6 is an appearance diagram illustrating an example of a detailed configuration of the ST board 2 in FIG. 1. (a) in the diagram illustrates the lower surface of the ST board 2, and (b) in the diagram illustrates the upper surface of the ST board 2.

On the lower surface of the ST board 2, the multiple lower electrodes 22 are arranged. The lower electrodes 22 are formed in positions respectively corresponding to the opening parts 31 of the unit attachment plate 3. That is, for each of the probe units 5, the lower electrodes 22 are orderly arranged along the pair of opposite sides of the probe substrate 50 with keeping away from the arrangement area for the probe unit 5.

On the upper surface of the ST board 2, the multiple upper surface electrodes 21 are arranged. The upper surface electrodes 21 are orderly arranged in a two-dimensional manner, and the pitch therebetween is larger than that between the lower surface electrodes 22 that are linearly orderly arranged. In the diagram, the upper surface electrodes 21 are orderly arranged in a matrix for each of the probe units 5.

In addition, in the case where the unit attachment plate 3 is made of electrically conductive metal, it is desirable to arrange an insulating film between the ST board 2 and the unit attachment plate 3. The insulating film may be formed on the ST board 2, or can also be formed on the unit attachment plate 3. For example, in the case of forming an insulating film on the unit attachment plate 3 to, in addition to the surface facing to the ST board 2, insulate the opening parts 31, any of the electrically conductive wires 54 may come into contact with a corresponding opening part 31, and therefore the workability of the wire bonding can be improved.

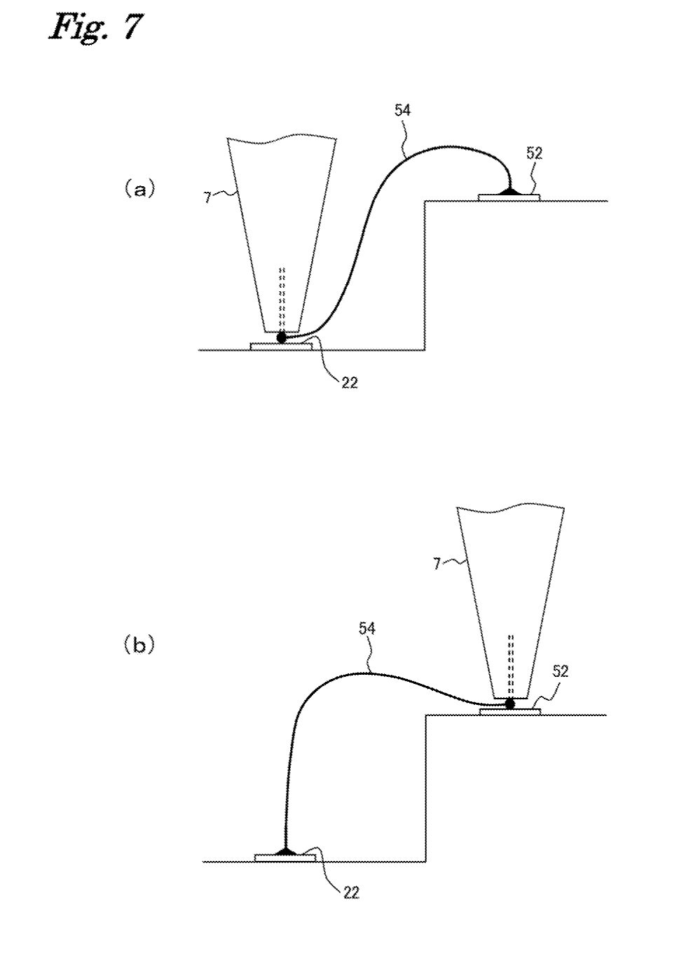

FIG. 7 is a schematic diagram illustrating an example of a method for forming each of the electrically conductive wires 54. (a) in the diagram illustrates a situation of connecting the electrically conductive wire 54 to a corresponding one of the probe electrodes 52 first, and then connecting the electrically conductive wire 54 to a corresponding one of the lower surface electrodes 22. On the other hand, (b) in the diagram illustrates a situation of connecting the electrically conductive wire 54 to the lower surface electrode 22 first, and then connecting the electrically conductive wire 54 to the probe electrode 52. Note that a capillary 7 is a tool of the bonding machine, which supplies the electrically conductive wire 54 from a taper-shaped fore end.

In (a) in the diagram, first, the fore end of the capillary 7 is brought close to the probe electrode 52 to connect the electrically conductive wire 54 to the probe electrode 52. Then, after the capillary 7 has been horizontally moved, the electrically conductive wire 54 is bent by a predetermined amount, and further, the capillary 7 is moved so as to be brought close to the ST board 2 to connect the electrically conductive wire 54 to the lower surface electrode 22. For this reason, in the opening part 31, the electrically conductive wire 54 can be arranged with being inclined, so that the capillary 7 is unlikely to interfere with an adjacent electrically conductive wire 54, and therefore an interval between electrically conductive wires 54 adjacent to each other can be narrowed.

In (b) in the diagram, first, the fore end of the capillary 7 is brought close to the lower surface electrode 22 to connect a fore end of the electrically conductive wire 54 to the lower surface electrode 22. Then, after the capillary 7 has been moved away from the ST board 2, the electrically conductive wire 54 is bent by a predetermined amount, and further, the capillary 7 is horizontally moved to connect the electrically conductive wire 54 to the probe electrode 22. For this reason, in the opening part 31, the electrically conductive wire 54 can be arranged so as to be nearly vertical to the ST board 2, so that the capillary 7 is unlikely to interfere with the opening part 31, and therefore the opening part 31 can be decreased in size. Also, the electrically conductive wire 54 is arranged so as to extend substantially horizontally from the probe electrode 22, and therefore a height of the electrically conductive wire 54 from a corresponding probe substrate 50 can be kept low.

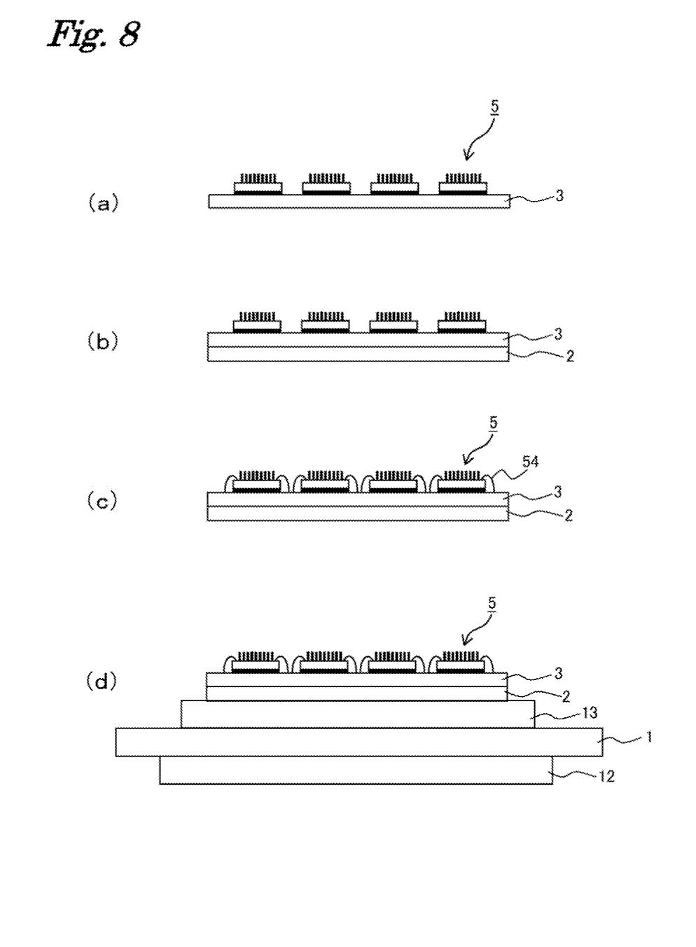

FIG. 8 is an explanatory diagram schematically illustrating an example of a method for manufacturing the probe card 100 in FIG. 1. First, the two or more probe units 5 are respectively bonded to the unit attachment plate 3 ((a) in FIG. 8). At this time, in order to accurately position and then arrange the probe units 5, on the lower surface of the unit attachment plate 3, positioning symbols are formed in advance.

Then, the unit attachment plate 3 attached with the probe units 5 is fastened on the ST board 2 with use of a bonding agent or a fastening screw ((b) in FIG. 8). Subsequently, by using the wire bonding machine, the probe electrodes 52 of the probe units 5, and the lower electrodes 22 of the ST board 2, which are exposed through the opening parts 31 of the unit attachment plate 3, are connected to each other by the electrically conductive wires 54 ((c) in FIG. 8).

Finally, the guide plate 13 is used to attach the ST board 2 on the main board 1. The attachment of the ST board 2 on the main board 1 is performed in the same manner as that for a conventional probe card.

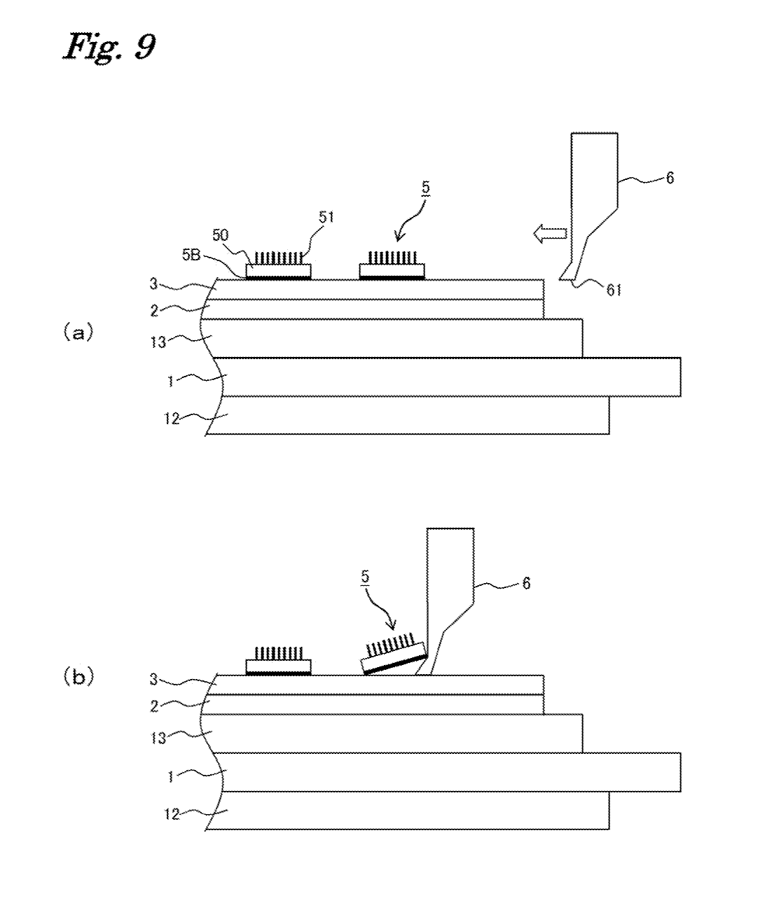

FIG. 9 is a diagram illustrating a situation at the time of repairing the probe card 100 in FIG. 1, in which (a) and (b) illustrate situations before and after the removal of a probe unit 5, respectively. The probe substrate 50 of the probe unit 5 is fastened on the unit attachment plate 3 through the bonding layer 5B. By pressing a wedge-shaped protrusion 61 of a shear tool 6 into the bonding layer 5B, the probe unit 5 is torn off from the unit attachment plate 3. That is, by using the shear tool 6 to spread out a distance between the probe substrate 50 and the unit attachment plate 3, the bonding layer is sheared off to remove the probe substrate 50 from the unit attachment plate 3.

After that, by attaching a new probe unit 5 and bonding an electrically conductive wire 54, the probe card 100 is repaired. In addition, even in the case of attaching the new probe unit 5 to the unit attachment plate 3 for the repair, the positioning symbol of the unit attachment plate 3 can be used to accurately perform positioning.

In the probe card 100 according to the present embodiment, the unit attachment plate 3 having the opening parts 31 exposing the lower surface electrodes 22 of the ST board 2 is fastened on the ST board 2, and on the unit attachment plate 3, the probe units 5 are fastened. That is, with paths for the electrical connections between the ST board 2 and the probe units 5 being ensured, the unit attachment plate 3 is made to intervene between the ST board 2 and the probe units 5, and the probe units 5 are not directly fastened on the ST board 2. For this reason, when a probe unit 5 is removed for repair, the ST board 2 can be suppressed from being damaged.

Also, in the unit attachment plate 3, an attachment surface thereof for the probe units 5 can be easily flattened as compared with the ST board 2 formed with the wiring pattern and the insulating film. For this reason, the attachment of the probe units 5 at the time of manufacturing or the attachment of a probe unit 5 at the time of repair can be facilitated. For example, positioning of the one or more probe units 5 can be facilitated, or fixation of the one or more probe units 5 can be facilitated.

Note that in the present embodiment, an example of the case where each of the probe substrates 50 is a silicon substrate is described; however, the present invention is not only limited to such a case. That is, each of the probe substrates 50 is only required to be a substrate made of an electrically non-conductive material, and as the probe substrate 50, a semiconductor substrate made of a material other than silicon can also be used, or an insulating substrate such as a glass substrate or a ceramic substrate can also be used.

Also, in the above embodiment, an example of the case where on the one probe card 100, the two or more probe units 5 are arranged is described; however, the present invention is not only limited to such a case. That is, on one probe card 100, one probe unit 5 may be arranged.

Further, in the present embodiment, as a method for manufacturing the probe card 100, an example of assembly order of the main board 1, ST board 2, unit attachment plate 3, and probe units 5 is described; however, it should be appreciated that such members can be assembled in any order. For example, the probe units 5 can also be fastened on the unit attachment plate 3 fastened on the ST board 2.

### Second Embodiment

In the first embodiment, the probe card 100 that is manufactured by fastening the two or more preliminarily separated probe units 5 on the unit attachment plate 3 is described. On the other hand, in the present embodiment, a probe card 101 that is manufactured by fastening two or more probe units 5 formed on a common probe substrate 50 on a unit attachment plate 3 as a unit, and then mutually separating the respective probe units 5 is described.

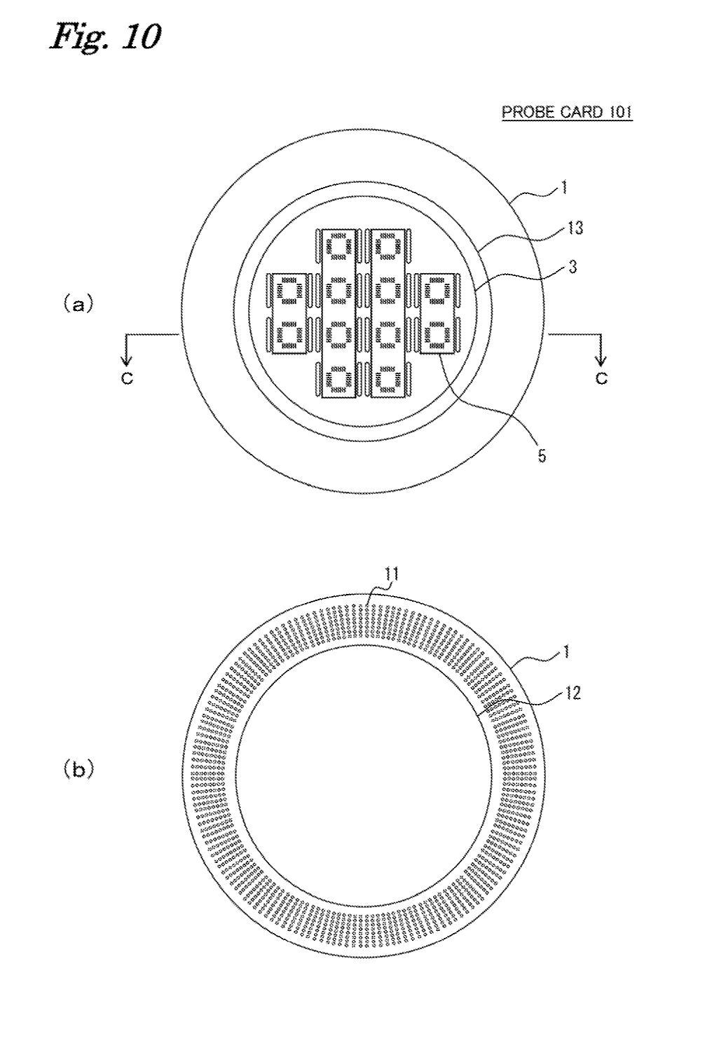

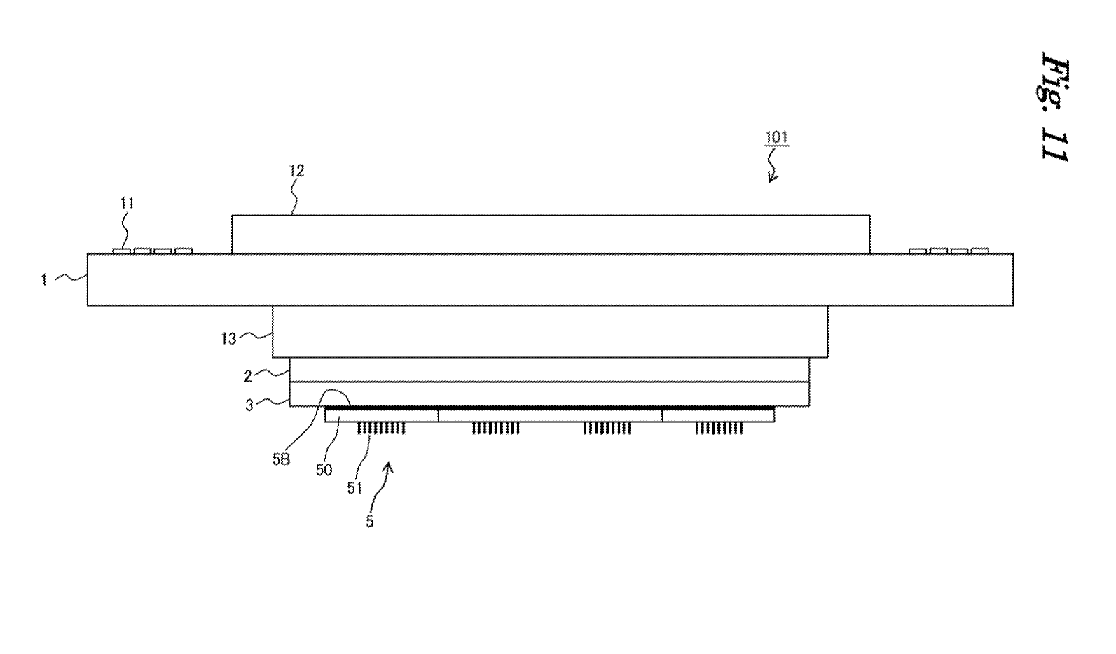

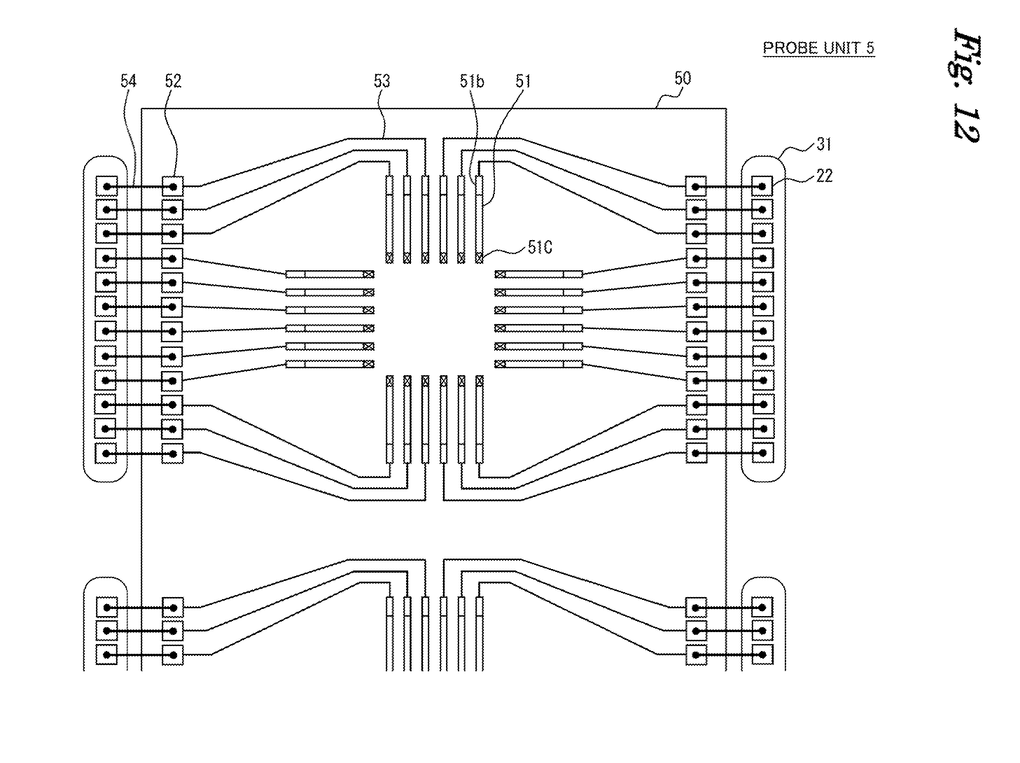

FIGS. 10 and 11 are appearance diagrams illustrating an example of a schematic configuration of the probe card 101 according to the second embodiment of the present invention. (a) in FIG. 10 illustrates a lower surface of the probe card 101, and (b) in FIG. 10 illustrates an upper surface of the probe card 101. Also, FIG. 11 illustrates a lateral side of the probe card 101. Further, FIG. 12 is an enlarged view illustrating the part of the lower surface of the probe card 101 in FIG. 10 with enlarging the part, in which one of the probe units 5 and its periphery are illustrated.

The probe card 101 is configured to include a main board 1, an ST board 2, a unit attachment plate 3, and probe units 5. As compared with the probe card 100 (first embodiment) in FIG. 1, a shape of each of the probe units 5 is different; however, the rest of the configuration is the same as that of the probe card 100 in FIG. 1. For this reason, corresponding components are affixed with the same symbols to omit redundant description thereof.

In the probe card 100 in FIG. 1, each of the probe units 5 is related to one electronic circuit, and therefore the respective probe units 5 have the same shape and are two-dimensionally arranged on the unit attachment plate 3. On the other hand, in the probe card 101, each of the probe units 5 is vertically arrayed, and related to all of one or more electronic circuits that are simultaneously inspected. For this reason, each of the probe units 5 has a vertically long rectangular shape, and the respective probe units 5 are horizontally orderly arranged on the unit attachment plate 3.

That is, each of the probe units 5 is related to the two or more electronic circuits that are arrayed in the one direction, and has a configuration in which the probe unit 5 in FIG. 3 is repetitively formed in the one direction. Note that, here, the unit attachment plate 3 has a disk shape, and therefore the number of related electronic circuits is different for each of the probe units 5, and horizontal lengths of the respective probe units 5 are the same but vertical lengths of the respective probe units 5 are different.

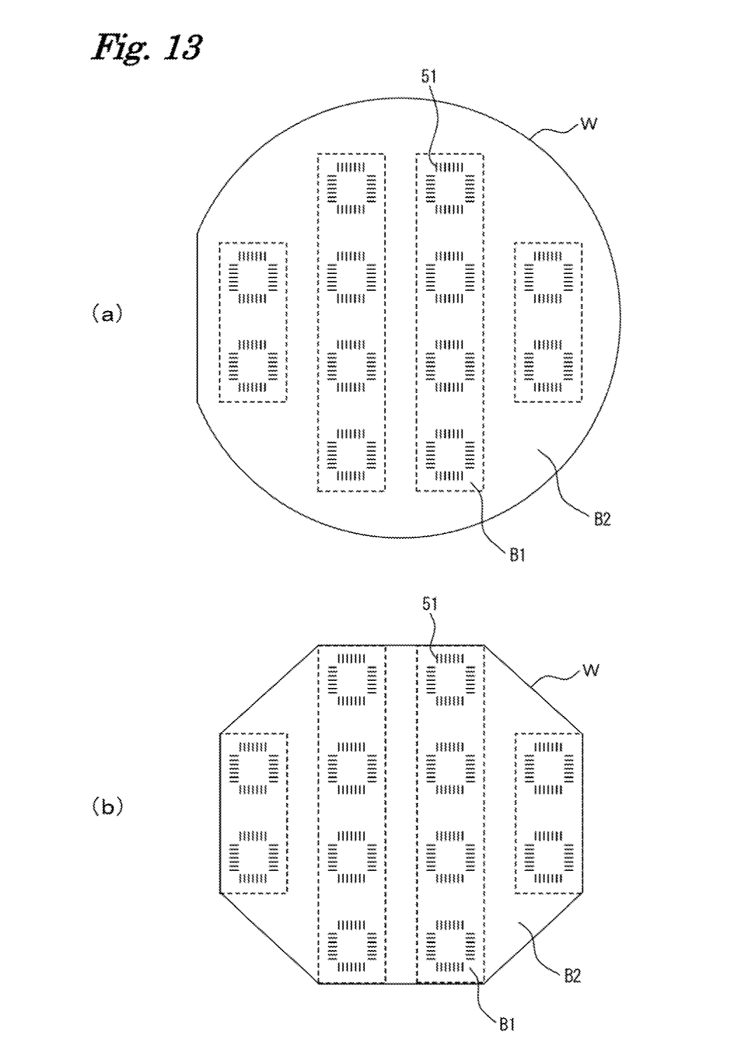

FIGS. 13 to 15 are explanatory diagrams schematically illustrating an example of a method for manufacturing the probe card 101 in FIG. 10. (a) in FIG. 13 illustrates a multi-probe substrate W corresponding to the two or more probe units 5.

The multi-probe substrate W is divided into two or more device areas B1 respectively corresponding to the probe units 5, and the other wiring area B2, and in each of the device areas B1, contact probes 51, probe electrodes 52, and a wiring pattern 53 are formed. Also, arrangement of the device areas B1 on the multi-probe substrate W is made to coincide with arrangement of the probe units 5 on the unit attachment plate 3. For this reason, areas facing to the lower surface electrodes 22 of the ST board 2 are included in the wiring area B2. That is, the multi-probe substrate W is the probe substrate 50 common to the two or more probe units 5, and keeps a relative positional relationship on the unit attachment plate 3. It is here assumed that as the multi-probe substrate W, a silicon wafer is used.

First, on one of principal surfaces of the multi-probe substrate W, the contact probes 51, probe electrodes 52, and wiring patterns 53 are formed. For example, on the multi-probe substrate W, a resist layer made of photoresist is formed and patterned, and an electrically conductive layer is formed by sputtering, whereby the probe electrodes 52 and wiring patterns 53 are formed. Further, by an electroplating method, an electrically conductive layer is stacked on the multi-probe substrate W, and thereby the contact probes 51 are formed.

(b) in FIG. 13 illustrates a state where an outer frame of the multi-probe substrate W is cut off. The multi-probe substrate W formed with the contact probes 51, probe electrodes 52, and wiring patterns 53 is cut by using a dicing machine to remove an outer frame part positioned outside the device areas B1 in the wiring area B2. The dicing machine is a cutting apparatus that rotates a disk-shaped rotary blade to cut an object to be machined.

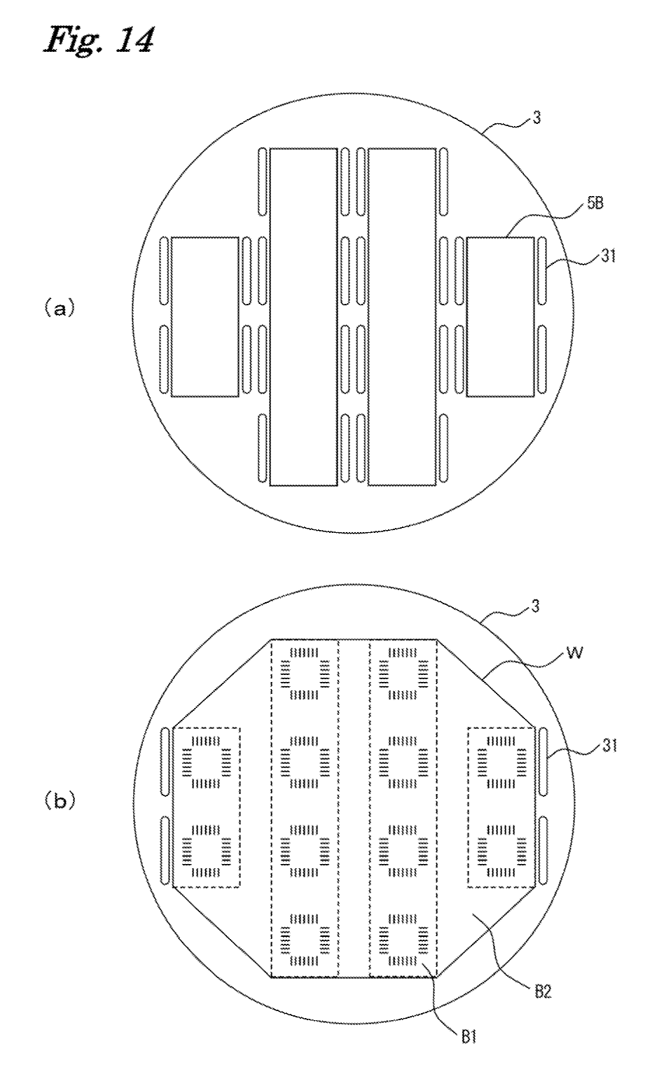

(a) in FIG. 14 illustrates a state where the bonding layer 5B is formed on the unit attachment plate 3. The bonding layer 5B is formed in areas corresponding to the device areas B1 on the multi-probe substrate W. For example, by attaching bonding sheets, which have been respectively cut so as to have sizes and shapes corresponding to the device areas B1, on the unit attachment plate 3, the bonding layer 5B can be formed. Alternatively, a bonding sheet attached on the unit attachment plate 3 may be cut to remove an unnecessary bonding sheet. The bonding sheet is a film-like bonding agent, and as the bonding sheet, a high Tg material such as polyimide resin or polyamide resin, or a thermoplastic bonding agent including, as a main ingredient, a material having a low linear expansion coefficient or cure shrinkage factor is used.

(b) in FIG. 14 illustrates a state where on the unit attachment plate 3 formed with the bonding layer 5B, the multi-probe substrate W of which the outer frame has been cut is fastened. The multi-probe substrate W of which the outer frame part has been removed is positioned with respect to the unit attachment plate 3, and then fastened on the unit attachment plate 3. For example, by heating any of the multi-probe substrate W and the unit attachment plate 3 sandwiching the bonding layer 5B, or pressing the multi-probe substrate W against the unit attachment plate 3 to apply pressure to them, the bonding layer 5B is cured, and the multi-probe substrate W is fastened on the unit attachment plate 3.

By fastening the multi-probe substrate W on the unit attachment plate 3, the opening parts 31 arranged between the probe units 5 are covered by the multi-probe substrate W. That is, only lower surface electrodes 22 that are arranged outside the outermost probe units 5 are brought into a state of being exposed, and lower electrodes 22 arranged between the probe units 5 are brought into a state of being covered by the multi-probe substrate W.

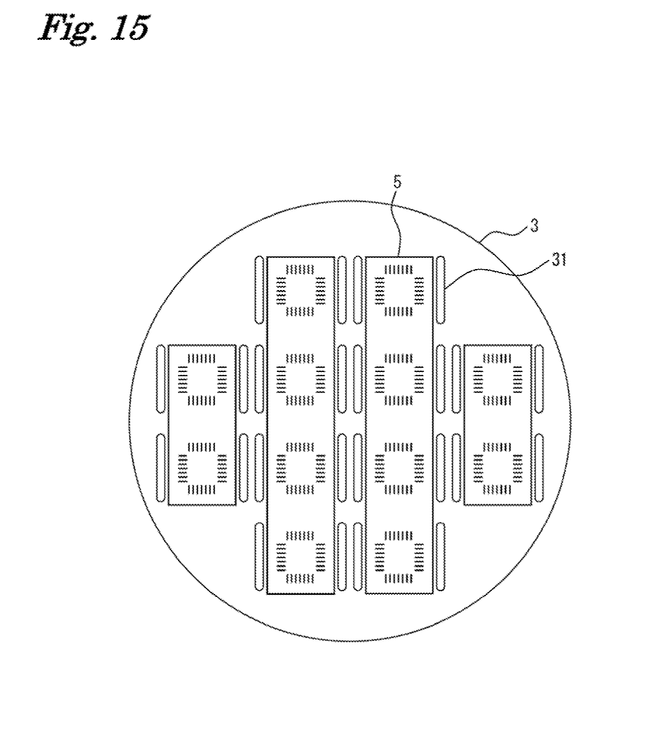

FIG. 15 illustrates a state where from the multi-probe substrate W fastened on the unit attachment plate 3, the wiring area B2 are removed. The multi-probe substrate W fastened on the unit attachment plate 3 is cut by using the dicing machine, and thereby the wiring area B2 is removed. By removing the wiring area B2, the respective device areas B1 are separated as the two or more probe units 5. For this reason, opening parts 31 that are arranged between the probe units 5 and covered by the multi-probe substrate W are exposed, and thereby the lower surface substrates 22 corresponding to the opening parts 31 are exposed.

The multi-probe substrate W may be separated after the unit attachment plate 3 has been fastened on the ST board 2; however, the separation is preferably performed before the fastening on the ST board 2. After the separation of the multi-probe substrate W, in the same manner as that in the first embodiment, through a wire bonding step, and a step of attachment to the main board 1, the probe card 101 is completed.

In the probe card 101 according to the present embodiment, by fastening the multi-probe substrate W including the two or more probe units 5 on the unit attachment plate 3, and then removing the wiring area B2 from the multi-probe substrate W, the separation into the two or more probe units 5 is performed. For this reason, the two or more probe units 5 can be simultaneously attached on the unit attachment plate 3, and therefore as compared with the case of fastening two or more preliminarily separated probe units 5 on the unit attachment plate 3, positioning can be easily performed and also accuracy of the positioning can be improved. Further, work of attaching the probe units 5 can be simplified.

### Third Embodiment

In the second embodiment, an example of the method for manufacturing the probe card 101, which after the fastening on the unit attachment plate 3, separates the multi-probe substrate W into the two or more probe units 5 by using the dicing machine is described. On the other hand, in the present embodiment, a method for manufacturing a probe card 101, which fastens a multi-probe substrate W preliminarily formed with split grooves on a unit attachment plate 3, and then separates probe units 5 by applying external force such as impact or pressure is described.

In addition, by using the manufacturing method according to the present invention, the probe card having the same configuration as that of the probe card 101 in the second embodiment can be manufactured. Also, regarding the same steps as those in the second embodiment, redundant description is omitted.

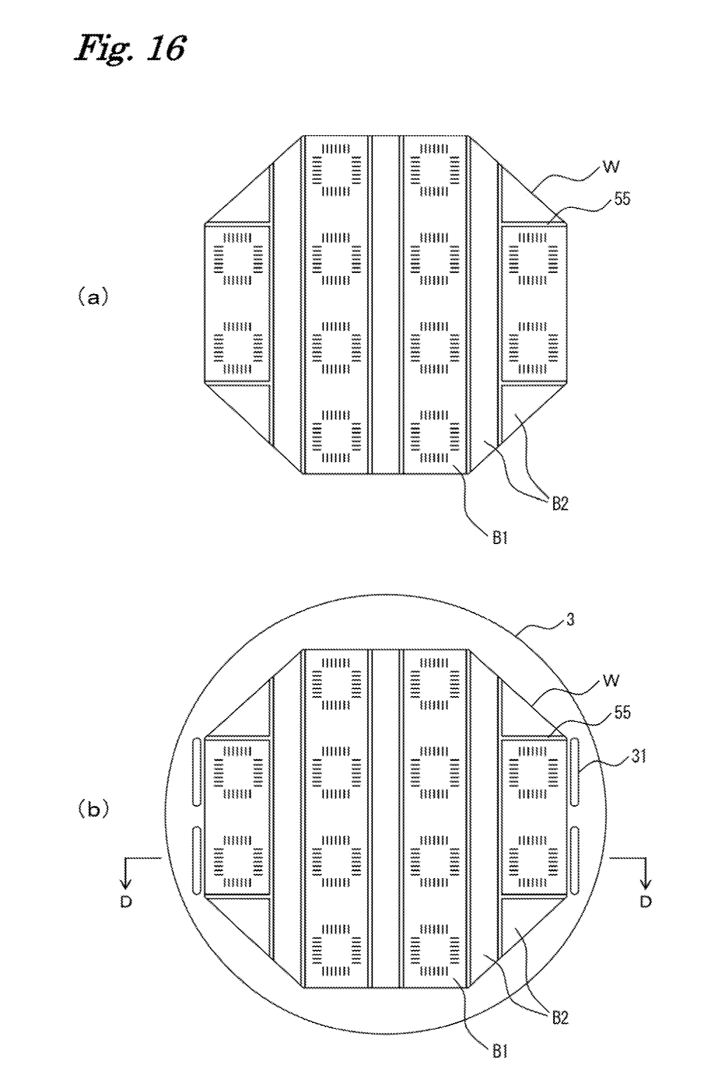

FIG. 16 is an explanatory diagram schematically illustrating an example of the method for manufacturing the probe card 101 according to the third embodiment of the present invention. (a) in FIG. 16 illustrates a state where on the multi-probe substrate W of which an outer frame is removed, the split grooves 55 are formed along boundaries between the device areas B1 and the wiring areas B2. The split grooves 55 are groove parts that are, in order to facilitate work of separating the multi-probe substrate W into the device areas B1 and the wiring area B2, formed on a principal surface of the multi-probe substrate W. The split grooves 55 are cutting grooves that are formed by using, for example, a dicing machine, and before fastening on the unit attachment plate 3, formed on the multi-probe substrate W of which an outer frame part is removed.

(b) in FIG. 16 illustrates a state where on the unit attachment plate 3 formed with the bonding layer 5B, the multi-probe substrate formed with the split grooves 55 is fastened. As the unit attachment plate 3 formed with the bonding layer 5B, the same plate as that illustrated in (a) of FIG. 14 is used. The multi-probe substrate W is, after having been fastened on the unit attachment plate 3, split along the split grooves 55 to remove the wiring regions B2 and also mutually separate the two or more device areas B1. The multi-probe substrate W is split by being applied with impact or pressure. After that, in the same manner as that in the first embodiment, through the wire bonding step and the step of attachment to the main board 1, the probe card 101 is completed.

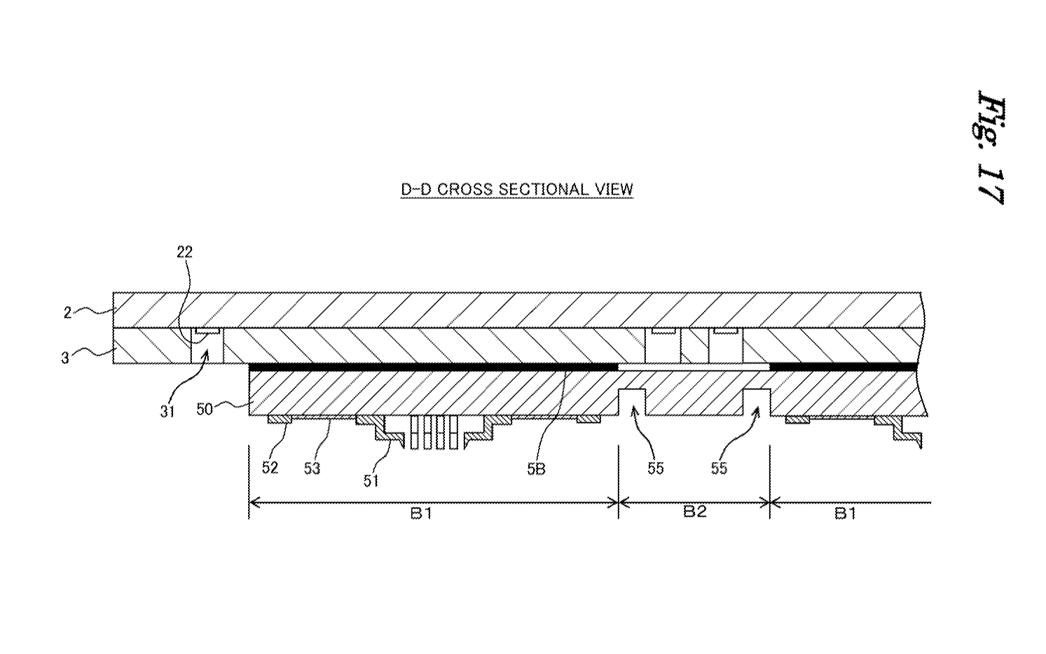

FIG. 17 illustrates a cross-sectional view in the case of cutting the multi-probe substrate W along a D-D section line in (b) of FIG. 16. The multi-probe substrate W is divided into the device areas B1 and the wiring areas B2, and at the boundaries between the areas B1 and B2, the split grooves 55 are formed. The split grooves 55 are the cutting grooves formed by using the dicing machine, and in the multi-probe substrate W, a thickness in the split grooves 55 is thinner than a thickness of the above-described other areas. For this reason, by applying the external force to the multi-probe substrate W, the multi-probe substrate W is split along the split groove 55. At this time, the wiring areas B2 not formed with the bonding layer 5B are removed, whereas the two or more device areas B1 formed with the bonding layer 5B are separated into the probe units 5 respectively corresponding thereto.

According to the present embodiment, the multi-probe substrate W is formed with the split grooves 55 before being fastened on the unit attachment plate 3, and after having been fastened on the unit attachment plate 3, split by being applied with the external force such as impact or pressure. For this reason, at the time of splitting the multi-probe substrate W, the contact probes 51 on the multi-probe substrate W can be suppressed from being damaged.

Also, the split grooves 55 are formed on the multi-probe substrate W formed with the contact probes 51. For this reason, as compared with the case of forming the contact probes 51 on the multi-probe substrate W formed with the split grooves 55, a step of forming the contact probes 51 can be simplified to reduce manufacturing cost.

### Fourth Embodiment

In the second embodiment, the example of the method for manufacturing the probe card 101, which after the fastening on the unit attachment plate 3, separates the multi-probe substrate W by using the dicing machine is described. On the other hand, in the present embodiment, a method for manufacturing a probe card 102, which after fastening on an ST board 2, separates a multi-probe substrate W by using a dicing machine is described. That is, the case of applying the manufacturing method in the second embodiment to the method for manufacturing the probe card 102 not having the unit attachment plate 3 is described. In addition, regarding the same steps as those in the second embodiment, redundant description is omitted.

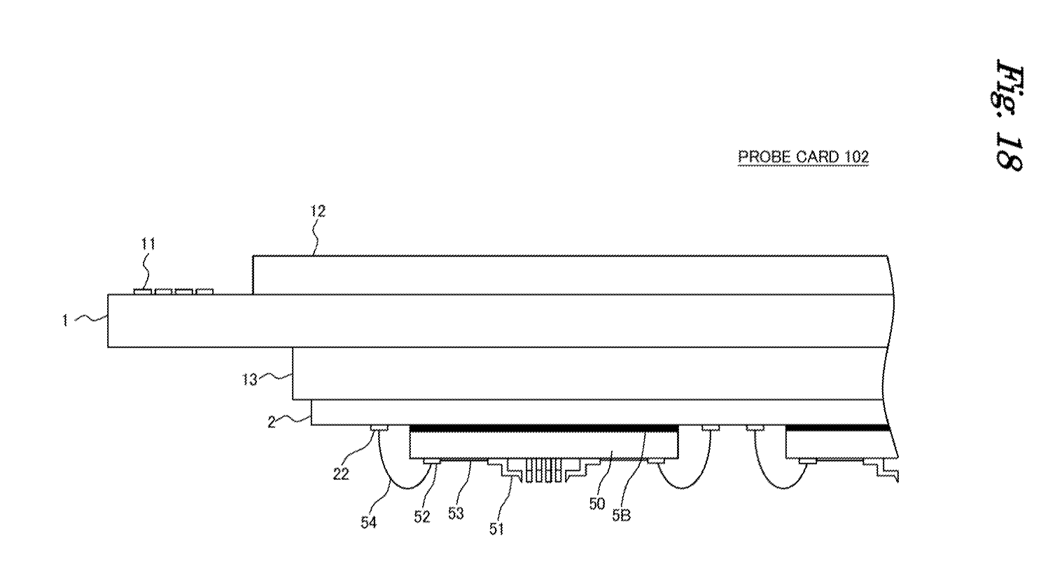

FIG. 18 is an appearance diagram illustrating an example of a schematic configuration of the probe card 102 according to the fourth embodiment of the present invention, in which a lateral side of the probe card 102 is illustrated. The probe card 102 is, as compared with the probe card 101 (second embodiment), different in that the probe card 102 is not provided with the unit attachment plate 3. The rest of the configuration is the same as that in the second embodiment, and therefore corresponding components are affixed with the same symbols to omit redundant description thereof.

On the lower surface of the ST board 2, the two or more probe units 5 are fastened, and the probe electrodes 52 are connected to the lower surface electrodes 22 of the ST board 2 by the electrically conductive wires 54. In addition, shapes and arrangement of the respective probe units 5 are the same as those of the probe units 5 in FIG. 10.

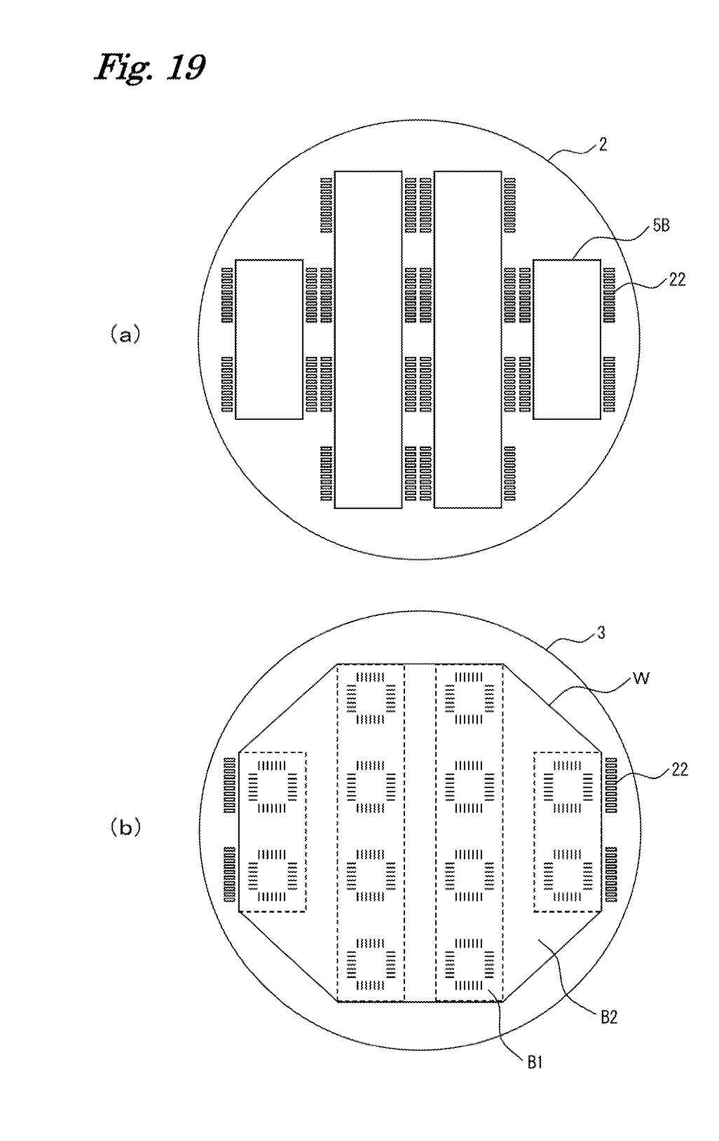

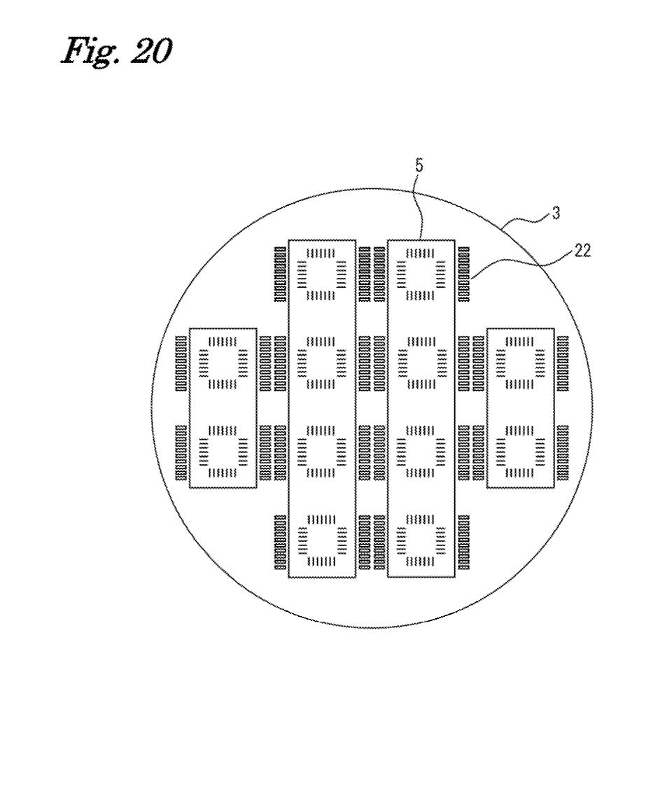

FIGS. 19 and 20 are explanatory diagrams schematically illustrating the method for manufacturing the probe card 101 in FIG. 18. (a) in FIG. 19 illustrates a state where on the ST board 2, the bonding layer 5B is formed. The bonding layer 5B is formed in areas corresponding to the device areas B1 on the multi-probe substrate W. For example, by attaching bonding sheets, which have been respectively cut so as to have sizes and shapes corresponding to the device areas B1, on the ST board 2, the bonding layer 5B can be formed. Alternatively, a bonding sheet attached on the ST board 2 may be cut to remove an unnecessary bonding sheet.

(b) in FIG. 19 illustrates a state where on the unit attachment plate 3 formed with the bonding layer 5B, the multi-probe substrate W of which the outer frame has been cut off is fastened. The multi-probe substrate W of which the outer frame part has been removed is positioned with respect to the ST board 2, and then fastened on the ST board 2. For example, by heating any of the multi-probe substrate W and the ST board 2 sandwiching the bonding layer 5B, or pressing the multi-probe substrate W against the ST board 2 to apply pressure, the bonding layer 5B is cured, and the multi-probe substrate W is fastened on the ST board 2.

FIG. 20 illustrates a state where from the multi-probe substrate W fastened on the ST board 2, the wiring areas B2 are removed. The multi-probe substrate W fastened on the ST board 2 is cut by using the dicing machine to remove the wiring areas B2. By removing the wiring areas B2, the respective device areas B1 are separated into the two or more probe units 5, and also the lower electrodes 22 of the ST board 2, which are arranged between the probe units 5, are exposed. After that, in the same manner as that in the first embodiment, through the wire bonding step, and the step of attachment to the main board 1, the probe card 101 is completed.

In the probe card 101 according to the present embodiment, the multi-probe substrate W including the two or more probe units 5 is fastened on the ST board 2, and then from the multi-probe substrate W, the wiring areas B2 are removed, whereby the two or more mutually separated probe units 5 are attached on the ST board 2. For this reason, as compared with the case of fastening two or more preliminarily separated probe units 5 on the ST board 2, positioning can be easily performed, and also positioning accuracy can be improved.

### Fifth Embodiment

In the third embodiment, an example of the method for manufacturing the probe card 101, which after the fastening on the unit attachment plate 3, separates the multi-probe substrate W having the split grooves 55 by applying the external force such as impact or pressure is described. On the other hand, in the present embodiment, an example of a method for manufacturing a probe card 102, which after fastening on an ST board 2, separates a multi-probe substrate W having split grooves 55 by applying external force such as impact or pressure is described. That is, the case of applying the manufacturing method in the third embodiment to the method for manufacturing the probe card 102 not having the unit attachment plate 3 is described.

In addition, by using the manufacturing method according to the present embodiment, the probe card having the same configuration as that of the probe card 102 in the fourth embodiment can be manufactured. Also, regarding the same steps as those in the third or fourth embodiment, redundant description is omitted.

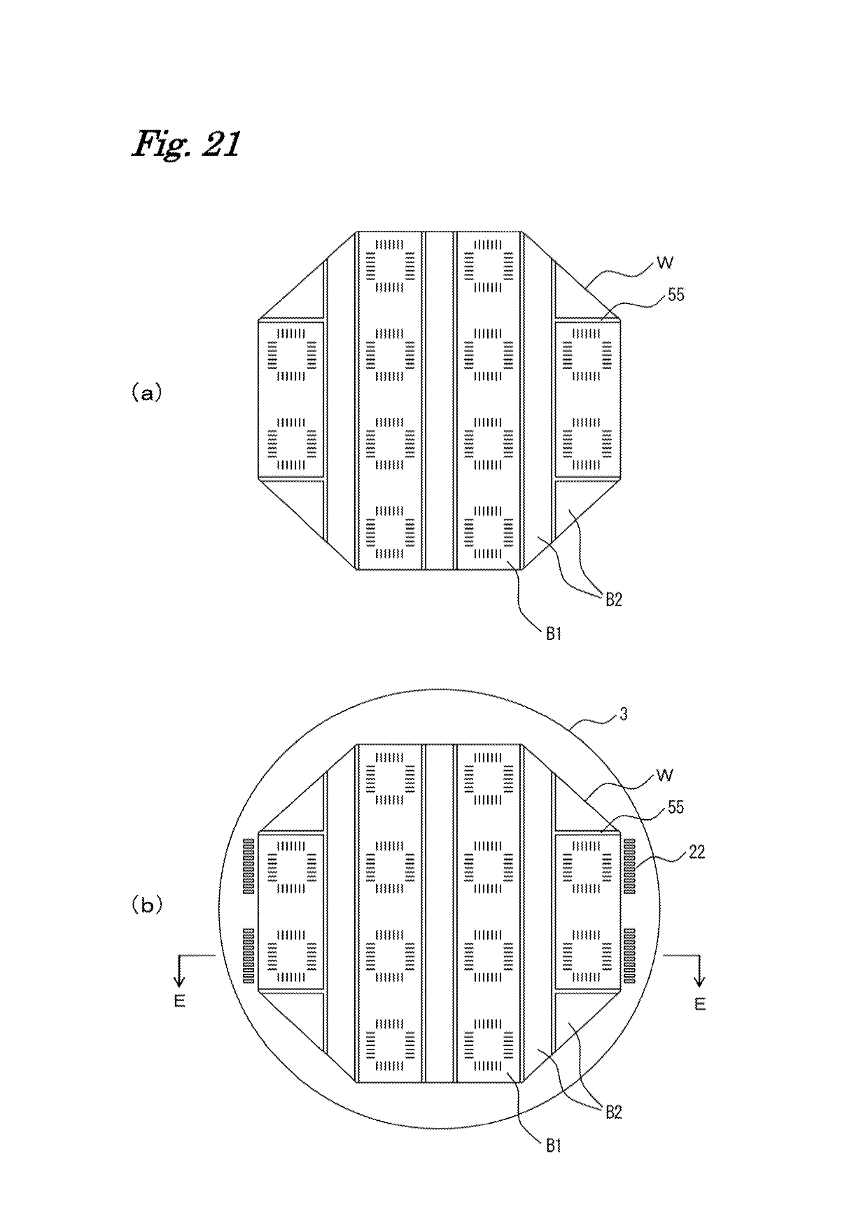

FIG. 21 is an explanatory diagram schematically illustrating the example of the method for manufacturing the probe card 102 according to the fifth embodiment of the present invention. (a) in FIG. 21 illustrates a state where on the multi-probe substrate W of which the outer frame is removed, the split grooves 55 are formed along boundaries between the device areas B1 and the wiring areas B2. The split grooves 55 are, before the fastening on the unit attachment plate 3, formed on the multi-probe substrate W, which is formed with the contact probes 51 and of which the outer frame part is removed.

(b) in FIG. 21 illustrates a state where on the ST board 2 formed with the bonding layer 5B, the multi-probe substrate W formed with the split grooves 55 is fastened. As the ST board 2 formed with the bonding layer 5B, the same board as that illustrated in (a) of FIG. 19 is used. The multi-probe substrate W is, after having been fastened on the unit attachment plate 3, split along the split grooves 55 to remove the wiring areas B2, and consequently separated into the two or more device areas B1. The multi-probe substrate W is split by being applied with impact or pressure. After that, in the same manner as that in the first embodiment, through the wire bonding step and the step of attachment to the main board 1, the probe card 102 is completed.

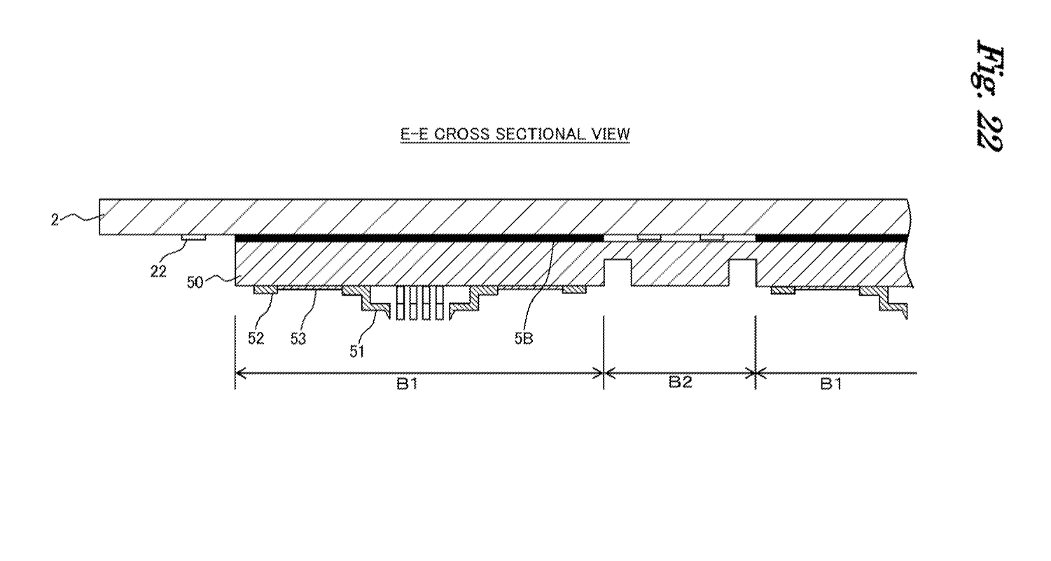

FIG. 22 illustrates a cross-sectional view in the case of cutting along an E-E section line in (b) of FIG. 21. The multi-probe substrate W is divided into the device areas B1 and the wiring areas B2, and at the boundaries between the areas B1 and B2, the split grooves 55 are formed. The split grooves 55 are cutting grooves formed by using a dicing machine, and in the multi-probe substrate W, a thickness in the split grooves 55 is thinner than a thickness of the above-described other areas. For this reason, by applying the external force to the multi-probe substrate W, the multi-probe substrate W is split along the split grooves 55. At this time, the wiring areas B2 not formed with the bonding layer 5B are removed, whereas the two or more device areas B1 formed with the bonding layer 5B are separated into the probe units 5 respectively corresponding thereto.

According to the present embodiment, on the multi-probe substrate W before being fastened on the ST board 2, the split grooves 55 are formed, and also the multi-probe substrate W after having been fastened on the ST board 2 is applied with the external force such as impact or pressure and thereby split. For this reason, at the time of splitting the multi-probe substrate W, the contact probes 51 on the multi-probe substrate W can be suppressed from being damaged.

Also, by forming the split grooves 55 on the multi-probe substrate W formed with the contact probes 51, as compared with the case of forming the contact probes 51 on the multi-probe substrate W formed with the split grooves 55, a step of forming the contact probes 51 can be simplified to reduce manufacturing cost.

Note that, in the above-described third or fifth embodiment, describes is the example of the case of using the dicing machine to form the cutting grooves on the multi-probe substrate W, and thereby providing the split grooves 55; however, the present invention is not only limited to such a case. That is, it is only necessary that the split grooves 55 as reduced thickness parts can be formed on the multi-probe substrate W, and the split grooves 55 may be provided by another fabrication method. For example, by etching the multi-probe substrate W having been formed with the contact probes 51, the split grooves 55 may be formed on the multi-probe substrate W.

Also, in any of the above-described second to fifth embodiments, the example of the case of fastening the multi-probe substrate W of which the outer frame has been removed on the unit attachment plate 3 is described; however, the present invention is not only limited to such a case. That is, the present invention can also be configured to, after fastening on the unit attachment plate 3, remove the outer frame from the multi-probe substrate W. For example, the present invention can also be configured to, at the time of removing the wiring areas B2, simultaneously remove the outer frame.

### DESCRIPTION OF REFERENCE NUMERALS

1 Main board
11 External terminal
12 Reinforcing plate
13 Guide plate
14 Internal electrode of main board
15 Wiring pattern of main board
16 Connecting pin
2 ST board
21 Upper surface electrode
22 Lower surface electrode
23 Wiring pattern
3 Unit attachment plate
31 Opening part
5 Probe unit
5B Bonding layer
50 Probe substrate
51 Contact probe
51b Base part of contact probe
51c Contact part of contact probe
52 Probe electrode
53 Wiring pattern
54 Electrically conductive wire
55 Split groove
6 Shear tool
61 Wedge-shaped protrusion
100 to 102 Probe card
B1 Device area
B2 Wiring area
W Multi-probe substrate

What is claimed is:

1. A probe card comprising:
a wiring substrate that is formed with an electrode terminal;
a unit attachment plate that is fastened on said wiring substrate and formed with an opening part exposing said electrode terminal;
a probe unit that includes a probe substrate formed with a contact probe and a probe electrode and is fastened on said unit attachment plate; and
an electrically conductive wire that connects said electrode terminal and said probe electrode to each other through said opening part.

2. The probe card according to claim 1, wherein:
two or more said electrode terminals are exposed from said opening part in common; and
two or more said probe electrodes on said probe unit are respectively connected to corresponding ones of said electrode terminals through two or more electrically conductive wires passing through said opening part in common.

3. The probe card according to claim 2, wherein:
two or more probe units are arranged on said unit attachment plate in common; and
said opening part has a long narrow shape that extends along outer edge parts of said probe units.

4. A probe card manufacturing method comprising:
a step of fastening a probe substrate formed with a contact probe and a probe electrode on a unit attachment plate;
a step of fastening said unit attachment plate on a wiring substrate with relating an opening part of said unit attachment plate to an electrode terminal of said wiring substrate; and
a step of performing wire bonding between said probe electrode and said electrode terminal exposed through said opening part.

5. The probe card manufacturing method according to claim 4, comprising
a step of, after the fastening on said unit attachment plate, removing a part of said probe substrate to expose said opening part covered by said probe substrate.

6. The probe card manufacturing method according to claim 5, comprising
a step of forming a split groove on said probe substrate, wherein
in said step of removing the part of said probe substrate, impact is applied to said probe substrate to split the probe substrate along said split groove.

7. The probe card manufacturing method according to claim 5, wherein
in said step of removing the part of said probe substrate, a dicing machine is used to cut said probe substrate.

8. The probe card manufacturing method according to claim 5, comprising
a step of forming a bonding layer on said wiring substrate with relating the bonding layer to a formation area for said contact probe and said probe electrode, wherein
in said step of fastening said probe substrate on said wiring substrate, through said bonding layer, said probe substrate is fastened on said wiring substrate.
